(19) United States
(12) Patent Application Publication
(10) Pub. No.: US 2009/0169942 A1
(43) Pub. Date: Jul. 2, 2009

(54) Physical Vapor Deposited Nano-Composites for Solid Oxide Fuel Cell Electrodes

(75) Inventors: Joshua L. Hertz, Newark, DE (US); Harry L. Tuller, Wellesley, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Massachusetts Institute of Technology, Cambridge, MA (US)

(21) Appl. No.: 11/988,764

(22) PCT Filed: Jul. 18, 2006
(86) PCT No.: PCT/US2006/027744

§ 371 Date: Jan. 6, 2009

(51) Int. Cl. H01M 4/02; B32B 5/16; B05D 5/12; C23C 14/34; C23C 14/30; H01M 8/10; H01M 4/86

(52) U.S. Cl. 429/30; 428/323; 427/115; 204/192.1; 427/596; 428/221; 429/44

(57) ABSTRACT

Thin-film composite materials with nanometer-scale grains comprise a thin-film layer that includes at least an electronic and an ionic conductor, and can be porous and/or resistant to redox-degradation. The thin-film composite materials can be formed by simultaneous co-deposition of at least an electronic and an ionic conductor onto a substrate using physical vapor deposition methods. Sacrificial materials can be co-deposited with the electronic and ionic conductors and subsequently removed from the thin-film layer to form a network of pores in the thin-film layer, that is, a porous thin-film composite material. A solid oxide fuel cell comprises an anode, an electrolyte and a cathode, wherein the anode and cathode are independently a thin-film composite material and the electrolyte is a thin-film material. Particularly, redox-degradation resistant thin-film composite materials can be used both as anodic and cathodic electrodes, which allows fabrication of fuel cell stacks with symmetric thermo-mechanical properties, thereby increasing mechanical stability. The nanometer-scale grain size and intimate phase mixing in these composites leads to increased reaction kinetics, and therefore is expected to yield increased power output from fuel cell stacks employing these thin-film composite materials.

### RELATED APPLICATION

This application claims the benefit of U.S. Provisional Application No. 60/700,696 filed on Jul. 18, 2005. The entire teachings of the above application are incorporated herein by reference.

### GOVERNMENT FUNDING

This invention was made with Government support under Contract No. DAAD-01-1-0566 awarded by the U.S. Army. The Government has certain rights in this invention.

### BACKGROUND OF THE INVENTION

Solid oxide fuel cells (SOFCs) normally need to operate at very high temperatures (>800° C.) in order to activate the sluggish kinetics. However, such high temperatures increase the processing and operational costs of traditional SOFCs and would be difficult to maintain in a portable microfabricated SOFC (μSOFC) device. Therefore, there is the need to decrease the operating temperatures, and increase the electrode kinetics through the use of improved electrode materials.

### SUMMARY OF THE INVENTION

This invention generally relates to thin-film composite materials with nanometer-scale grains produced by physical vapor deposition that can be used as electrodes in a SOFC, and especially within a μSOFC.

One embodiment of the invention is a thin-film composite material with nanometer-scale grains which comprises a thin-film layer that includes an electronic conductor and an ionic conductor.

Another embodiment of the invention is a method of forming a thin-film composite material with nanometer-scale grains comprising co-depositing simultaneously onto a substrate at least an electronic conductor and an ionic conductor to form a thin-film layer onto the substrate.

Yet another embodiment of the invention is a solid oxide fuel cell, comprising an anode, an electrolyte and a cathode, wherein the anode and the cathode are independently a thin-film composite material with nanometer-scale grains, comprising a thin-film layer that includes an electronic conductor and an ionic conductor.

The thin-film composite materials of the invention have nanometer-scale grains and thus allow for intimate phase mixing, leading to increased reaction kinetics and consequent increased power output from SOFC devices employing these materials. The materials described herein can simplify μSOFC device fabrication since a composite of electronic and ionic conducting materials can be used in planar configuration without a need for lithography to create the electrochemically-active three-phase boundary regions (where gas, electron conductor and ion conductor phases all intersect). In addition, materials can be selected which are relatively stable in both oxidizing and reducing environments, and so may be used for both the anode and the cathode. This further eases device fabrication by reducing the number of materials and processes needed. It also allows for fabrication of fuel cell stacks (anode/electrolyte/cathode) with symmetric thermo-mechanical properties, thereby increasing the mechanical stability of the device.

### BRIEF DESCRIPTION OF DRAWINGS

FIG. 1 shows microelectrodes of 250 nm thick nanoscale Pt—YSZ composite deposited on a YSZ single crystal that were used to determine the area-specific electrochemical resistance.

FIG. 2 presents experimental data for the electrochemical conductances per area for a) composite PT-YSZ microelectrodes of difference diameter and thickness 1 and b) dense platinum electrodes 2.

FIG. 3 shows a cross section of a sputtered, symmetric thin-film stack of Pt—YSZ, YSZ and Pt—YSZ as a prototype μSOFC device.

### DETAILED DESCRIPTION OF THE INVENTION

The invention is directed to thin-film composite materials with nanometer-scale grains that comprise a thin-film layer that includes an electronic conductor; and an ionic conductor.

An electronic conductor is a material that conducts electrons. Most preferably, the electronic conductor is a noble metal. However, a combination of noble metals may be desirable for improved catalytic properties. The noble metal is most preferably platinum, but can be gold to save costs or another of ruthenium, rhodium, palladium, osmium or iridium for their unique catalytic properties, especially as concerns the catalysis of the oxidation of petroleum or alcohol-based fuels in a SOFC, including μSOFC. The noble-metals used in this invention are preferably of high purity. Preferably, the electronic conductor can be an alloy of noble metals to enhance the electrochemical properties of the thin-film composite material, whereby it is preferable that the noble metals constitute the majority concentration.

An ionic conductor is a material that conducts ions. An ionic conductor can be a conductor of protons, oxygen ions, fluorine ions, copper ions, silver ions, or alkali metal ions. Preferably, the ionic conductor is an oxygen ion conductor. More preferably, the ionic conductor can be stabilized zirconia, doped ceria, lanthanum strontium gallium magnesium oxide, doped bismuth oxide, a bimevox-type structure, or an oxygen conducting pyrochlore. The excellent stability of the zirconia materials may make them preferable; however, better performance may be found when using the other materials. Stabilized zirconia can be calcium- or scandium-stabilized zirconia (CSZ/SSZ), but preferably is yttria-stabilized zirconia (YSZ). Doped ceria is preferably gadolinium- or samarium doped ceria.

The thin-film layer comprises grains of nanometer-scale sizes. Each grain consists of either the material of an electronic conductor or the material of an ionic conductor and consists of one phase. Accordingly, each grain is either a conductor of electrons or ions. The network of electron conducting grains corresponds to the electronic conductor phase and the network of ion conducting grains corresponds to the ionic conductor phase.

The composition range of the thin-film composite material is limited by the need for the electronic conductor grains and the ionic conductor grains to form at least two inter-penetrating, continuous networks. A continuous network is a network of grains that is continuous throughout the film-layer and is conducting, either for electrons or ions, that is, it is either an interconnected electron conductor (also called herein “electron conductor”) or an interconnected ionic conductor (also called herein “ionic conductor”).

Preferably, the electronic conductor constitutes about 25% to about 75% by volume of the thin-film layer and the ionic conductor constitutes about 25% to about 75% by volume of the thin-film layer. Most preferably, the electronic conductor constitutes about 50% by volume of the thin-film layer and the ionic conductor constitutes about 50% by volume of the thin-film layer. The latter volume percentages are most preferred, because they give the highest probability that both the electron- and ion-conducting phases are percolated through the structure and possibly the highest interface density between the two phases, wherein interface density refers to the length of triple phase boundary length per unit volume of the thin film layer. Composition ranges can be adjusted to possibly optimize the interface density for a particular grain size distribution, to create a coefficient of thermal expansion that matches a substrate or electrolyte on which the thin-film composite may be deposited, or to provide sufficient lateral electronic conductivity.

The “maximum diameter” of a grain is the longest of all lengths between any two points on the surface of the grain. “Nanometer-scale grains” are grains that have maximum diameters in the range from about 1 nm to about 1000 nm. It is believed that the performance of thin-film composite materials as electrodes is linearly dependent upon the triple-phase boundary length, and that, therefore, the average grain size of the grains in the thin-film layer should be minimized. Preferably, the grains have an average maximum diameter of less than about 100 nm. More preferably, the grains have an average maximum diameter of less than about 50 nm. Most preferably, the grains have an average maximum diameter of less than about 10 nm.

The thickness of the thin-film layer of the thin-film composite material is at least 50 nm to maintain mechanical integrity. For practical purposes, that is, to keep the processing time that is needed to create the thin-film composite material practical, the maximum of the thin-film layer thickness generally should be in the range of 250 nm to 5 μm. The preferred thickness of the thin-film layer is 500 nm.

Redox-degradation includes destructive expansion of a metal when it oxidizes. Also, oxides may decompose under highly oxidizing or reducing conditions. A material is “resistant to redox-degradation” if it is stable under highly oxidizing or reducing conditions, that is, if it maintains its oxidation state and mechanical integrity under these conditions. Stabilized zirconia and all of the noble metals are highly resistant to redox-degradation. Doped ceria and other oxygen ion conductors as components of an electrode are sufficiently resistant to redox degradation. Thus, all of the thin-film composite materials disclosed herein can be used in both anodic and cathodic electrodes.

In another embodiment of the invention, the thin film layer further includes a sacrificial material that is insoluble in either of the electronic and ionic conductors, whereby the electronic and ionic conductors and the sacrificial material are distinct phases in the thin-film layer. Also preferably, the sacrificial material is a polymeric material. More preferably, the sacrificial material is polyethylene or polytetrafluoroethylene. Sacrificial materials other than polymeric materials can be used, but they generally should be insoluble in both the electronic conductor and ionic conductor phases, and they must be removable by thermal or chemical means in a way that leaves the electronic conductor and ionic conductor phases intact.

As in the case of thin-film composite material without sacrificial material, the composition range of the thin-film composite material generally requires the electronic conductor grains and the ionic conductor grains to form at least two inter-penetrating, continuous networks. Preferably, the electronic conductor constitutes about 25% to about 75% by volume of the thin-film layer, the ionic conductor constitutes about 25% to about 75% by volume of the thin-film layer and the sacrificial material constitutes about 25% to about 75% by volume of the thin-film layer. More preferably, the electronic conductor constitutes about 33% by volume of the thin-film layer, the ionic conductor constitutes about 33% by volume of the thin-film layer and the sacrificial material constitutes about 33% by volume of the thin-film layer.

In another embodiment of the invention the sacrificial material is removed from the thin-film layer to create a continuous network of pores in the thin-film layer, and thus a porous thin-film composite material. It is believed that, by creating a continuous network of pores in the thin-film layer of the thin-film composite material the triple phase boundary length between the electronic conductor, the ionic conductor and the gas phase is increased, and thus the performance of electrodes that employ the thin-film composite material is improved. Preferably, all of the sacrificial material is removed from the thin-film layer to thereby maximize porosity of the thin-film layer. However, some sacrificial material can remain at least partially embedded within the electronic and/or ionic conductor material subsequent to removal of the sacrificial material from the thin-film layer.

Preferably, with respect to the porous thin-film composite material, the electronic conductor constitutes about 50% by volume of the thin-film layer and the ionic conductor constitutes about 50% by volume of the thin-film layer. The latter volume percentages are most preferred, because they give the highest probability that both the electron- and ion-conducting phases are percolated through the structure and possibly the highest interface density (i.e., triple phase boundary length) between the two remaining phases.

Another embodiment of the invention is a method of forming a thin-film composite material with nanometer-scale grains, comprising co-depositing simultaneously onto a substrate at least a) an electronic conductor, and b) an ionic conductor, to form a thin-film layer onto the substrate. Preferably, co-depositing includes use of physical vapor deposition methods, such as those known in the art. More preferably, sputtering, pulsed laser deposition, electron beam evaporation or thermal evaporation is used. A combination of methods can also be used, for example, one phase deposited by sputtering (e.g., the phase of the electronic conductor) and one phase deposited by thermal evaporation (e.g., the phase of the ionic conductor). For each of the electronic and ionic conductor materials a separate method could be used. The ability to achieve such small grain sizes is one of the benefits of producing these composite materials by physical deposition methods, such as sputtering.

Preferably, the substrate is at least one of silicon, silicon carbide, aluminum oxide, silica, stabilized zirconia, a SOFC cathode material, a SOFC anode material, or a SOFC electrolyte material. More preferably, the substrate is yttria-stabilized zirconia.

In a more specific embodiment of the invention, the electronic conductor and the ionic conductor are co-deposited in an atmosphere and onto a substrate that can be heated, and further comprising the step of controlling the rate of co-deposition, the atmosphere and temperature of the substrate to thereby form the nanometer-scale grains. Factors that influence grain size include substrate temperature, substrate composition and substrate morphology, and sputtering gas pressure, sputtering gas composition, and sputtering power if sputtering is used as deposition method. Generally, increased temperature and/or decreased deposition rate increase the grain size. The effect of the sputtering atmosphere on grain size is non-trivial. Temperature, atmosphere, and deposition rates can be controlled using standard vacuum deposition tools as are described herein.

The atmosphere (hereinafter also co-deposition gas) can be a standard atmosphere known in the art used in sputtering or reactive sputtering, that is, an inert gas or an inert gas plus oxygen. The inert gas:oxygen co-deposition gas ratio (e.g., argon:oxygen co-deposition gas ratio) can be in the range from 100% oxygen to 100% inert gas, preferably, 50% inert gas and 50% oxygen. The inert gas is usually argon. Control of the deposition parameters can be by any of the standard methods used in thin film processing known in the art. Preferably, the atmosphere is a mixture of argon and oxygen at 10 mTorr of pressure. The pressure and co-deposition gas ratio can be controlled, for example, with mass flow controllers.

Co-deposition may result in amorphous materials that are not sufficiently conductive to electrons and/or oxygen ions to be useful as SOFC electrodes. Heating of the substrate during deposition can be used to help crystallize the phases and increase the grain size. The temperature of the substrate can be controlled, for example, by using a halogen lamp heater with a standard PID (Proportional, Integral, and Derivative) temperature controller. Alternatively, standard methods of applying heat and controlling the temperature of the substrate can also be used.

The desired volume percentages of electronic conductor, ionic conductor and possibly sacrificial material in the thin-film layer are achieved by adjusting the relative sputtering powers for the electronic conductor, ionic conductor and sacrificial material sputtering targets. “Sputtering power” is the amount of power supplied to the sputtering target, as controlled by a standard DC or RF sputtering machine power supply unit.

A “shadow mask” is a perforated piece of material that partially masks a substrate in order to control what portions of the substrate receive a film being deposited.

In a more specific embodiment of the invention with respect to the method of forming a thin-film composite material with nanometer-scale grains, the temperature of the substrate is controlled during co-deposition to thereby form an amorphous film, which is subsequently thermally annealed such that it crystallizes and phase-segregates to yield distinct phases of electronic and ionic conductors in the thin-film layer. Preferably, the deposition temperature is controllable within the range from room temperature to 500° C. Thermal annealing can be performed, for example, in a high temperature furnace. Preferably, the annealing temperature is controllable within the range from 500° C. to 2000° C.

In a further specific embodiment of the invention with respect to the method of forming a thin-film composite material with nanometer-scale grains, the electronic conductor and the ionic conductor are co-deposited simultaneously with a sacrificial material onto a substrate, the deposited sacrificial material, the deposited electronic and ionic conductors thereby forming distinct phases in the thin-film layer.

In a further specific embodiment of the invention with respect to the method of forming a thin-film composite material with nanometer-scale grains, the method comprises the step of removing the sacrificial material in the thin-film layer to form a continuous network of pores within the thin-film layer. Preferably, the sacrificial material is removed by either thermally decomposing the sacrifical material or chemically dissolving the sacrifical material.

In yet another specific embodiment of the invention with respect to the method of forming a thin-film composite material with nanometer-scale grains, co-depositing the electronic conductor and the ionic conductor onto a substrate further comprises controlling an argon:oxygen co-deposition gas ratio to thereby form an unstable oxide of the electronic conductor on the substrate, and decompose the unstable oxide of the electronic conductor to thereby form the electronic conductor, whereby a network of pores is formed in the thin-film layer. It is believed that a network of pores is formed, because the phase of the oxide of the electronic conductor takes up a larger volume then the phase of the electronic conductor. Preferably, the oxide of the electronic conductor is decomposed by heating the substrate and thus the oxide of the electronic conductor. Preferably, the electronic conductor is platinum and the unstable oxide of the electronic conductor is platinum oxide.

Another specific embodiment of the invention, is a solid oxide fuel cell, comprising an anode, an electrolyte and a cathode, wherein the anode and the cathode independently can be any of the thin-film composite materials disclosed above and the electrolyte is a thin-film material, that is, stabilized zirconia, doped ceria, lanthanum strontium gallium magnesium oxide, doped bismuth oxide, bimevox-type structure, or an oxygen conducting pyrochlore. Such a solid oxide fuel cell can be a microfabricated SOFC. Preferably, the anode and the cathode are the same thin-film composite material. Using the same thin-film composite material eases SOFC device fabrication by reducing the number of materials and processes needed. It also allows for fabrication of a SOFC, and more generally, of fuel cell stacks with symmetric thermo-mechanical properties, thereby increasing the mechanical stability of the devices. However, if the same thin-film composite material is used for both anodic and cathodic electrodes, the material should be resistant to redox-degradation. As discussed above, all of the thin-film composite materials disclosed herein can be used in both anodic and cathodic electrodes thus allow for the fabrication of devices with symmetric thermo-mechanical properties. Symmetric thermo-mechanical properties refers to having equal coefficient of thermal expansion above and below the center line of a membrane, wherein the membrane is the thin film stack of anode/electrolyte/cathode after removal of the underlying substrate. Symmetric thermo-mechanical properties substantially prevent creation of bending moments that often lead to cracking when the membrane is heated or cooled.

Another embodiment of the invention is a solid oxide fuel cell, comprising an anode, an electrolyte and a cathode, wherein the anode and the cathode independently can be a thin-film composite material as disclosed above, wherein the electronic conductor is platinum and the ionic conductor is an oxygen ion conductor and the electrolyte is a thin-film material comprising an oxygen ion conductor. Preferably, the oxygen ion conductor is yttria-stabilized zirconia.

The invention is described by the following examples which are not intended to be limiting in any way.

### EXEMPLIFICATION

### Thin-Film Composite Materials with Platinum as Electronic Conductor and YSZ as Ionic Conductor as Microelectrodes

Composite films (i.e., thin-film composite materials) of platinum and YSZ were produced by co-sputtering. Two separate targets were used, each loaded in an individual Kurt J. Lesker model Torus 2C sputtering gun. A high purity yttrium-zirconium metal alloy target, 5.08 cm in diameter and 0.635 cm thick was custom made by ACI Alloys (San Jose, Calif.). The 9% Y-91% Zr target was connected to an Advanced Energy (Fort Collins, Colo.) RFX-600 RF power supply operating at 13.56 MHz. A 99.99% pure platinum target, 5.08 cm in diameter by 0.3175 cm thick, produced by Birmingham Metal (Birmingham, UK), was connected to an Advanced Energy MDX-500 DC power supply. The composition was varied by adjusting the relative sputtering powers used with each target. The co-sputtering procedure took advantage of the noble character of the platinum by using a somewhat oxidizing sputtering environment in order to oxidize the YSZ phase and yet keep the platinum phase metallic. The sputtering atmosphere was either 1:9 or 5:95 oxygen:argon, always at a pressure of 1.33 Pa (10 mTorr).

The sputtering chamber was evacuated to a background pressure of <2·10⁻⁴ Pa (2·10⁻⁶ Torr) using a CTI Cryogenics (Chelmsford, Mass.) model Cryotorr 8 cryogenic pump and as measured with an ionization gauge. The pump down time required to reach this pressure was about 12 hr. In order to create oxidized films, oxygen was present in the sputtering atmosphere. The desired oxygen—argon ratio was introduced into the chamber using MKS Instruments (Wilmington, Mass.) model 1179A mass flow controllers, operated with a model 647C process controller. The mass flow controllers were connected to nominally pure oxygen and argon sources. The total flow rate was around 20 sccm but was actively adjusted in order to maintain a working pressure of 1.33 Pa (10 mTorr).

Halogen lamps behind the substrate were optionally used for heated depositions at 300° C. or 600° C. A thermocouple mounted near the substrate provided feedback to a Watlow (St. Louis, Mo.) Series 96 temperature controller. Substrates were brought to the deposition temperature using a ramp rate of about 5° C. per minute and allowed to equilibrate for at least 15 minutes before beginning deposition. After deposition was complete, heated substrates were set to cool at a similar rate, though the rate of cooling decreased near room temperature. The substrates were at an uncontrolled, floating bias and were rotated to create radially uniform film thickness. Substrates were situated horizontally at a distance of about 10 cm from the target.

Double side polished YSZ single crystals, 10 mm×10 mm square, were used as the electrolyte. A large area back electrode was formed by depositing the Pt—YSZ composite on one side of the crystal through a shadow mask that blocked only the outer ˜1 mm border of the crystal. Working microelectrodes were then formed by depositing the composite film through a stainless steel plate that was machined with five through-holes of different sizes: 1.5 mm, 2 mm, 2.5 mm, 3 mm, and 4 mm in diameter.

The chief electrical characterization method used in this research was electrochemical impedance spectroscopy (EIS). Impedance spectra were collected by a Solartron Analytical (Famborough, UK) model 1260 impedance analyzer, controlled by a computer running Scribner Associates' (Southern Pines, N.C.) ZPlot software, version 2.8d. Measurements were made from high frequency to low frequency, 10⁷ Hz to 10⁻³ Hz, stepped logarithmically. Signal amplitudes were 20 mV RMS, centered about 0 V DC bias.

Samples were measured in an open-air microprobe station, the Suss MicroTec (Waterbury Center, Vt.) model SOM4, modified by the addition of a small hot stage, the Linkam Scientific Instruments (Tadworth, UK) model TS1500. Samples were contacted with 250 μm diameter, 99.99% pure platinum wire from Birmingham Metal. The wires were formed into a loop and mounted in a Suss MicroTec PH150 manual XYZ positioner. The wires then made pressure contact to the electrodes, as determined by visual inspection through the probe station microscope. Measurements were done at temperatures between 150° C. and 400° C., the goal operating temperature of a μSOFC.

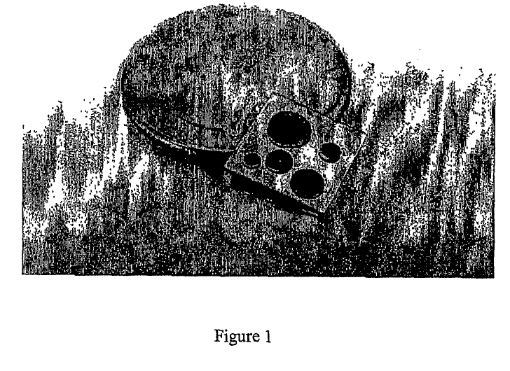

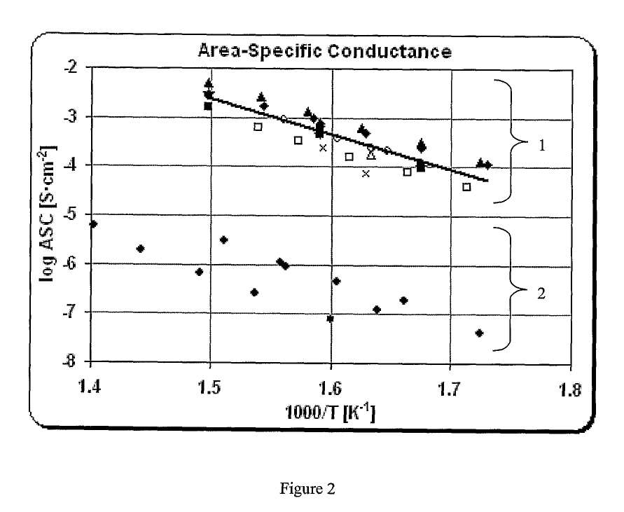

In one experiment, platinum and YSZ were co-sputtered from pure platinum and yttrium-zirconium alloy sputtering targets at 600° C. As evidenced by X-ray diffraction, processing at high temperatures is necessary to crystallize unique metallic and oxide phases. Adjusting the relative sputtering powers used with each target was successful in changing the relative platinum-to-YSZ film composition. The resulting films were electrochemically characterized by a microelectrode technique. The films were deposited through a shadow mask onto a single crystal YSZ with a large-area back electrode. The shadow mask formed the film into five circles of different diameter as shown in FIG. 1. Measurements indicate that the films have grain sizes of about 10 nm. The sample was placed on a hot stage and the microelectrodes were measured by impedance spectroscopy. The electrochemical resistance was measured as a function of temperature and electrode diameter (see FIG. 2). The resistance was found to decrease with increasing electrode diameter squared. The dependence on the electrode area, and not perimeter length as is found with the dense platinum electrodes used in model system studies, indicates that electrochemically active sites are found all over the surface. Per area, the composite structures are found to perform orders of magnitude better (i.e., have 3 orders of magnitude lower resistance per unit area) than the dense Pt IDE electrodes, presumably because of the increase in the number of active sites. The electrode is expected to be the dominant loss mechanism in a μSOFC, so the electrode resistance per area measured in this study can be correlated, with some assumptions, to a device power output. Extrapolating the resistances measured in this study yields an expected device output of around 2.5 mW/cm² at 433° C., 25 mW/cm² at 511° C. and 250 mW/cm² at 608° C.

Processing parameters that have been found preferable for the production of thin-film Pt—YSZ material are a sputtering gas pressure of about 10 mTorr with an argon:oxygen ratio of 9:1, a substrate temperature of about 600° C., a Pt target sputtering power of 20 W, and a Y_{0.09}Zr_{0.91} target sputtering power of 200 W.

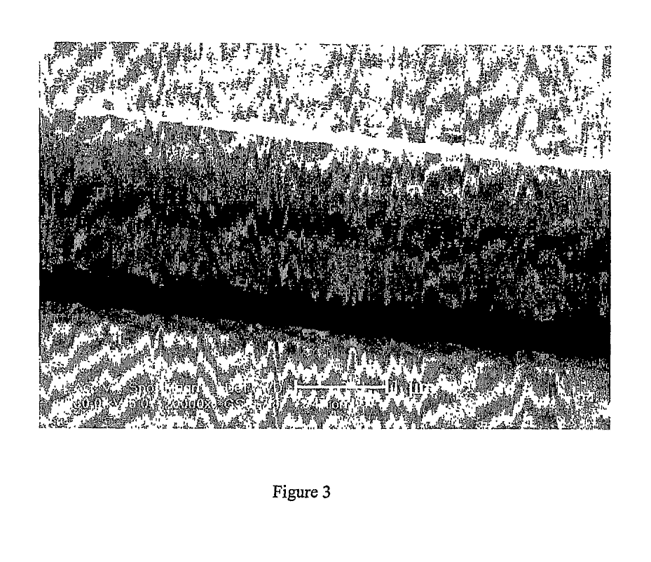

FIG. 3 shows a cross-section of a sputtered, symmetric thin-film stack of Pt—YSZ, YSZ and Pt—YSZ. Pt—YSZ, YSZ and Pt—YSZ have been sequentially sputtered onto a substrate to form a symmetric stack of thin-film composite material Pt—YSZ (that is, Pt as electronic conductor and YSZ as ionic conductor) corresponding to the anode of the resulting μSOFC, the thin-film material YSZ corresponding to the electrolyte of the resulting μSOFC, and thin-film composite material Pt—YSZ (that is, Pt as electronic conductor and YSZ as ionic conductor) corresponding to the cathode of the resulting μSOFC.

### Porous Thin-Film Composite Material

As a practical example of this technique, a polymeric phase such as polyethylene or polytetrafluoroethylene can be simultaneously co-sputtered with platinum and YSZ films and then removed by heat treatment at ˜400° C.

While this invention has been particularly shown and described with references to preferred embodiments thereof, it will be understood by those skilled in the art that various changes in form and details may be made therein without departing from the scope of the invention encompassed by the appended claims.

What is claimed is:

1. A thin-film composite material with nanometer-scale grains, comprising a thin-film layer that includes:
a) an electronic conductor; and
b) an ionic conductor.

2. The thin-film composite material of claim 1, wherein the electronic conductor includes one or more noble metals.

3. The thin-film composite material of claim 1, wherein the electronic conductor includes an alloy comprising one or more noble metals.

4. The thin-film composite material of claim 2, wherein the noble metal is at least one member from the group selected of platinum, gold, ruthenium, rhodium, palladium, osmium, and iridium.

5. The thin-film composite material of claim 1, wherein the ionic conductor includes an oxygen ion conductor.

6. The thin-film composite material of claim 5, wherein the oxygen ion conductor is at least one member from the group selected of stabilized zirconia, doped ceria, lanthanum strontium gallium magnesium oxide, doped bismuth oxide, bimevox-type structure, or an oxygen conducting pyrochlore.

7. The thin-film composite material of claim 1, wherein the electronic conductor constitutes about 25% to about 75% by volume of the thin-film layer and the ionic conductor constitutes about 25% to about 75% by volume of the thin-film layer.

8. The thin-film composite material of claim 1, wherein the electronic conductor constitutes about 50% by volume of the thin-film layer and the ionic conductor constitutes about 50% by volume of the thin-film layer.

9. The thin-film composite material of claim 1, wherein the nanometer-scale grains have an average maximum diameter of less than about 100 nm.

10. The thin-film composite material of claim 9, wherein the nanometer-scale grains have an average maximum diameter of less than about 50 nm in size.

11. The thin-film composite material of claim 1, wherein the electronic conductor and ionic conductor are resistant to redox-degradation.

12. The thin-film composite material of claim 1, wherein the thin-film layer further includes a sacrificial material that is insoluble in either of the electronic and ionic conductors, whereby the electronic and ionic conductors and the sacrificial material are in distinct phases in the thin-film layer.

13. The thin-film composite material of claim 12, wherein the sacrificial material includes a polymeric material.

14. The thin-film composite material of claim 13, wherein the polymeric material includes polyethylene or polytetrafluoroethylene.

15. The thin-film composite material of claim 12, wherein the electronic conductor constitutes about 25% to about 75% by volume of the thin-film layer, the ionic conductor constitutes about 25% to about 75% by volume of the thin-film layer and the sacrificial material constitutes about 25% to about 75% by volume of the thin-film layer.

16. The thin-film composite material of claim 12, wherein the electronic conductor constitutes about 33% by volume of the thin-film layer, the ionic conductor constitutes about 33% by volume of the thin-film layer and the sacrificial material constitutes about 33% by volume of the thin-film layer.

17. The thin-film composite material of any one of claims 12-16, wherein the sacrificial material has been removed to create a continuous network of pores in the thin-film layer.

18. A method of forming a thin-film composite material with nanometer-scale grains, comprising the step of co-depositing simultaneously onto a substrate at least
a) an electronic conductor; and
b) an ionic conductor,
to form a thin-film layer onto the substrate.

19. The method of claim 18, wherein co-depositing the electronic conductor and the ionic conductor includes at least one method selected from the group consisting of sputtering, pulsed laser deposition, electron beam evaporation and thermal evaporation.

20. The method of claim 18, wherein the substrate includes at least one member selected from the group consisting of silicon, silicon carbide, aluminum oxide, silica, stabilized zirconia, a SOFC cathode material, a SOFC anode material, and a SOFC electrolyte material.

21. The method of claim 18, wherein the electronic conductor and the ionic conductor are co-deposited in an atmosphere and onto a substrate that can be heated, and further comprising the step of controlling the rate of co-deposition, the atmosphere and temperature of the substrate to thereby form the nanometer-scale grains.

22. The method of claim 21, wherein the temperature of the substrate is controlled during co-depositing to thereby create an amorphous film, and further comprising thermally annealing the amorphous film to thereby crystallize and phase-segregate it.

23. The method of claim 18, wherein the electronic conductor and the ionic conductor are co-deposited simultaneously with a sacrificial material onto a substrate, the deposited sacrificial material and the deposited electronic and ionic conductors thereby forming distinct phases in the thin-film layer.

24. The method of claim 23, wherein the sacrificial material includes a polymeric material.

25. The method of claim 24, wherein the polymeric material includes polyethylene or polytetrafluoroethylene.

26. The method of claim 23, further comprising the step of removing the sacrificial material in the thin-film layer to form a continuous network of pores in the thin-film layer.

27. The method of claim 26, wherein removing the sacrificial material includes thermally decomposing the sacrifical material.

28. The method of claim 26, wherein removing the sacrificial material includes chemically dissolving the sacrifical material.

29. The method of claim 18, wherein the step of co-depositing the electronic conductor and the ionic conductor onto a substrate further comprises
controlling an argon:oxygen co-deposition gas ratio to thereby form an unstable oxide of the electronic conductor on the substrate, and decomposing the unstable oxide of the electronic conductor to thereby form the electronic conductor, whereby a network of pores is created in the thin-film layer.

30. The method of claim 29, wherein the electronic conductor is platinum and the unstable oxide of the electronic conductor is platinum oxide.

31. A solid oxide fuel cell, comprising an anode, an electrolyte and a cathode, wherein the anode and the cathode are independently a thin-film composite material with nanometer-scale grains, comprising a thin-film layer that includes an electronic conductor and an ionic conductor, and the electrolyte is a thin-film material.

32. The solid oxide fuel cell of claim 31, wherein the anode and the cathode are essentially the same composition of thin-film composite material.

33. The solid oxide fuel cell of claim 32, wherein the solid oxide fuel cell has symmetric thermo-mechanical properties.

34. The solid oxide fuel cell of claim 31, wherein the electronic conductor is platinum and the ionic conductor is an oxygen ion conductor and the electrolyte is a thin-film material comprising an oxygen ion conductor.

35. The solid oxide fuel cell of claim 34, wherein the oxygen ion conductor is yttria-stabilized zirconia.
